(19) United States
(12) Patent Application Publication
(10) Pub. No.: US 2026/0280357 A1
(43) Pub. Date: Sep. 17, 2026

(54) WIRELESS POWER TRANSMISSION DEVICE

(71) Applicant: Murata Manufacturing Co., Ltd., Kyoto-fu (JP)

(72) Inventors: Hisanari TAKAI, Nagaokakyo-shi (JP); Tatsuya HOSOTANI, Nagaokakyo-shi (JP); Takahiro NAGAI, Nagaokakyo-shi (JP)

(73) Assignee: Murata Manufacturing Co., Ltd., Kyoto-fu (JP)

(21) Appl. No.: 19/669,660

(22) Filed: May 6, 2026

Related U.S. Application Data
(63) Continuation of application No. PCT/JP2024/027408, filed on Jul. 31, 2024.

(30) Foreign Application Priority Data
Nov. 7, 2023 (JP) 2023-190215

(51) Int. Cl. H02J 50/70; H02J 50/12; H05K 7/20

(52) U.S. Cl. CPC H02J 50/70; H02J 50/12; H05K 7/209

(57) ABSTRACT

A wireless power transmission device includes a power-transmission resonant circuit mounted on a first principal surface of a circuit board; a noise suppression circuit mounted on the first principal surface and electrically connected to the power-transmission resonant circuit; a power semiconductor element mounted on the first principal surface and including a switching element applying a periodically-changing voltage to the power-transmission resonant circuit; a control circuit on the first principal surface and controlling the switching element; and a heat spreader thermally in contact with a second principal surface of the circuit board. An electrical pattern electrically connecting a switching node of the power semiconductor element to the noise suppression circuit is in the circuit board. The heat spreader dissipates heat generated by the power semiconductor element; and, in plan view, overlaps the entire control circuit, and does not overlap any of the power semiconductor element and the noise suppression circuit.

### CROSS-REFERENCE TO RELATED APPLICATIONS

This application claims benefit of priority to International Patent Application No. PCT/JP2024/027408, filed Jul. 31, 2024, and to Japanese Patent Application No. 2023-190215, filed Nov. 7, 2023, the entire contents of each are incorporated herein by reference.

### BACKGROUND

### Technical Field

The present disclosure relates to a wireless power transmission device.

### Background Art

Recently, demand for wireless power transfer technique has been increased. In wireless power transfer, since power is transmitted through an electromagnetic field generated by a power transmission coil and received by a power reception coil, radiated noise increases. Accordingly, countermeasures against radiated noise are essential.

As a technique for reducing electromagnetic noise, Japanese Unexamined Patent Application Publication No. 2012-84599 describes a heat-sink assembly. Japanese Unexamined Patent Application Publication No. 2021-44346 describes a structure of a mounting circuit board.

### SUMMARY

A circuit board of a wireless power transmission device includes a MOSFET (Metal Oxide Semiconductor Field Effect Transistor) serving as a switching element. The circuit board includes a drain pattern electrically connected to the drain of the MOSFET. The drain pattern of the circuit board functions as a part of an antenna, and causes occurrence of radiated noise. To reduce radiated noise, reducing the area of the drain pattern of the circuit board is effective. However, in a wireless power transmission device, when the area of the drain pattern of the circuit board is reduced, heat generated by the MOSFET may cause a local temperature rise in the circuit board. When a local temperature rise in the circuit board occurs, the wireless power transmission device has a problem of reduction in reliability of the circuit board.

When a heat sink is used in the wireless power transmission device to dissipate heat generated by the MOSFET, capacitive coupling between the heat sink and a drain portion of the MOSFET forms stray capacitance. In the wireless power transmission device, the stray capacitance provides a propagation path for noise, causing a problem of generating radiated noise.

When the entire circuit board is covered by using electromagnetic shield material, it is difficult for the wireless power transmission device to transmit power. In addition, the wireless power transmission device handles a high frequency in the megahertz (MHz) range. Therefore, when a heat sink is used in the wireless power transmission device, electromagnetic noise in a high frequency band propagates through stray capacitance formed due to capacitive coupling between the heat sink and a drain portion of the MOSFET, which causes the heat sink to serve as an antenna. Thus, a problem arises in that radiated noise is generated.

The present disclosure is made in view of the situation described above, and, in wireless power transfer operation, suppresses a local temperature rise in the circuit board and, at the same time, stabilize the electrical circuit operation while suppressing radiated noise.

A wireless power transmission device according to an aspect of the present disclosure includes a circuit board; a power-transmission resonant circuit mounted on a first principal surface of the circuit board; a noise suppression circuit that is mounted on the first principal surface of the circuit board and that is electrically connected to the power-transmission resonant circuit; a power semiconductor element that is mounted on the first principal surface of the circuit board and that includes a switching element which applies a periodically-changing voltage to the power-transmission resonant circuit; a control circuit that is mounted on the first principal surface of the circuit board and that controls the switching element; and a heat spreader that is thermally in contact with a second principal surface of the circuit board. An electrical pattern which electrically connects a switching node of the power semiconductor element to the noise suppression circuit is formed in the circuit board. The heat spreader dissipates heat which is generated by the power semiconductor element and which is transferred through the electrical pattern and the circuit board; overlaps the entire control circuit when viewed in a direction perpendicular to the first principal surface, forms a first stray capacitance with the control circuit, and causes ground potential of the control circuit to be stabilized through the first stray capacitance and causes radiation of electromagnetic noise to be suppressed; and does not overlap any of the power semiconductor element and the noise suppression circuit when viewed in the direction perpendicular to the first principal surface, and does not form a structural stray capacitance with any of the power semiconductor element and the noise suppression circuit.

According to the present disclosure, in wireless power transfer operation, a local temperature rise in a circuit board may be suppressed. At the same time, the electrical circuit operation may be stabilized with suppression of radiated noise.

### BRIEF DESCRIPTION OF THE DRAWINGS

FIG. 1 is a diagram illustrating the circuit configuration of a wireless power transceiver device including a wireless power transmission device according to a first embodiment;

FIG. 2 is a diagram illustrating a layout of the wireless power transmission device according to the first embodiment;

FIG. 3 is a diagram illustrating a layout of the wireless power transmission device according to the first embodiment;

FIG. 4 is a diagram illustrating a layout of a wireless power transmission device according to a second embodiment;

FIG. 5 is a diagram illustrating a layout of the wireless power transmission device according to the second embodiment;

FIG. 6 is a diagram illustrating the circuit configuration of a wireless power transceiver device including a wireless power transmission device according to a third embodiment;

FIG. 7 is a diagram illustrating a layout of the wireless power transmission device according to the third embodiment;

FIG. 8 is a diagram illustrating a layout of the wireless power transmission device according to the third embodiment;

FIG. 9 is a diagram illustrating a layout of a wireless power transmission device according to a fourth embodiment; and

FIG. 10 is a diagram illustrating a layout of the wireless power transmission device according to the fourth embodiment.

### DETAILED DESCRIPTION

Embodiments of the present disclosure will be described in detail below on the basis of the drawings. The embodiments do not limit the present disclosure. Needless to say, the embodiments are exemplary, and partial replacement or combination of components illustrated in different embodiments may be made. In a second embodiment and its subsequent embodiments, points common to those in a first embodiment will not be described, and only different points will be described. In particular, substantially the same operational effects caused by substantially the same configurations will not be described in each embodiment.

### FIRST EMBODIMENT

### Circuit Configuration of Wireless Power Transceiver Device

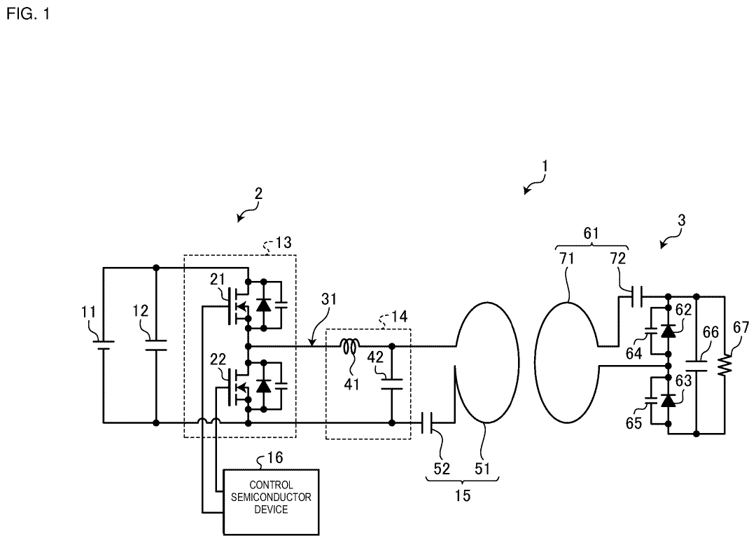

FIG. 1 is a diagram illustrating the circuit configuration of a wireless power transceiver device including a wireless power transmission device according to the first embodiment. A wireless power transceiver device 1 includes a wireless power transmission device 2 and a wireless power reception device 3.

The wireless power transmission device 2 includes a direct-current power supply 11, a smoothing capacitor 12, a power semiconductor device 13, a low-pass filter 14, a power-transmission resonant circuit 15, and a control semiconductor device 16.

The power semiconductor device 13 includes a transistor 21 and a transistor 22. Each of the transistor 21 and the transistor 22 has a parasitic capacitance and a parasitic diode.

In the present disclosure, each of the transistor 21 and the transistor 22 is assumed to be a MOSFET (Metal Oxide Semiconductor Field Effect Transistor). However, the present disclosure is not limited to this.

The low-pass filter 14 includes an inductor 41 and a capacitor 42.

The power semiconductor device 13 corresponds to an example of “power semiconductor element” of the present disclosure. The low-pass filter 14 corresponds to an example of “noise suppression circuit” of the present disclosure. The control semiconductor device 16 corresponds to an example of “control circuit” of the present disclosure.

The power-transmission resonant circuit 15 includes a power transmission coil 51 and a resonant capacitor 52.

The wireless power reception device 3 includes a power-reception resonant circuit 61, a diode 62, a diode 63, a capacitor 64, a capacitor 65, a smoothing capacitor 66, and a load 67.

The power-reception resonant circuit 61 includes a power reception coil 71 and a resonant capacitor 72.

The smoothing capacitor 12 is electrically connected, at its first end, to the high-potential-side terminal of the direct-current power supply 11. The smoothing capacitor 12 is electrically connected, at its second end, to the low-potential-side terminal of the direct-current power supply 11.

The drain of the transistor 21 is electrically connected to the first end of the smoothing capacitor 12. The source of the transistor 21 is electrically connected to the drain of the transistor 22. The source of the transistor 22 is electrically connected to the second end of the smoothing capacitor 12.

The inductor 41 is electrically connected, at its first end, to the drain of the transistor 22 through a drain pattern 31. The inductor 41 is electrically connected, at its second end, to a first end of the capacitor 42. The capacitor 42 is electrically connected, at its second end, to the source of the transistor 22.

The drain of the transistor 22 corresponds to an example of “switching node” of the present disclosure. The drain pattern 31 corresponds to an example of “electrical pattern” of the present disclosure.

The power transmission coil 51 is electrically connected, at its first end, to the first end of the capacitor 42. The power transmission coil 51 is electrically connected, at its second end, to a first end of the resonant capacitor 52. The resonant capacitor 52 is electrically connected, at its second end, to the second end of the capacitor 42.

The power reception coil 71 is electrically connected, at is first end, to a first end of the resonant capacitor 72. The resonant capacitor 72 is electrically connected, at its second end, to the cathode of the diode 62. The anode of the diode 62 is electrically connected to a second end of the power reception coil 71 and the cathode of the diode 63. The capacitor 64 is connected in parallel to the diode 62. The capacitor 65 is connected in parallel to the diode 63.

The smoothing capacitor 66 is electrically connected, at its first end, to the cathode of the diode 62. The smoothing capacitor 66 is electrically connected, at its second end, to the anode of the diode 63.

The load 67 is electrically connected, at its first end, to the first end of the smoothing capacitor 66. The load 67 is electrically connected, at its second end, to the second end of the smoothing capacitor 66.

The power-transmission resonant circuit 15 is electromagnetically coupled to the power-reception resonant circuit 61.

### Operation of Wireless Power Transceiver Device

The control semiconductor device 16 alternately switches the transistor 21 on and off inversely with the transistor 22 at a predetermined switching frequency. Accordingly, a rectangular-wave (pulse-like) voltage is applied to the power-transmission resonant circuit 15. The low-pass filter 14 cuts high-frequency components of the rectangular-wave voltage, and passes low-frequency components. The power-transmission resonant circuit 15 resonates in response to application of the rectangular-wave voltage, and a resonant current flows in the power-transmission resonant circuit 15.

When the power-transmission resonant circuit 15 resonates, the power-transmission resonant circuit 15 and the power-reception resonant circuit 61 resonate with each other. That is, the power-reception resonant circuit 61 resonates. As a result, a resonant current flows in the power-reception resonant circuit 61.

The frequency of a magnetic field generated by the power-transmission resonant circuit 15 is, for example, 6.78 MHz or 13.56 MHz in the ISM (Industrial, Scientific and Medical) band. However, the present disclosure is not limited to this.

The diode 62 and the diode 63 rectify the resonant current flowing through the power reception coil 71, and outputs the rectified current to the smoothing capacitor 66. The smoothing capacitor 66 smooths the rectified current. The voltage rectified by the smoothing capacitor 66 is applied to the load 67.

### Layout of Wireless Power Transmission Device

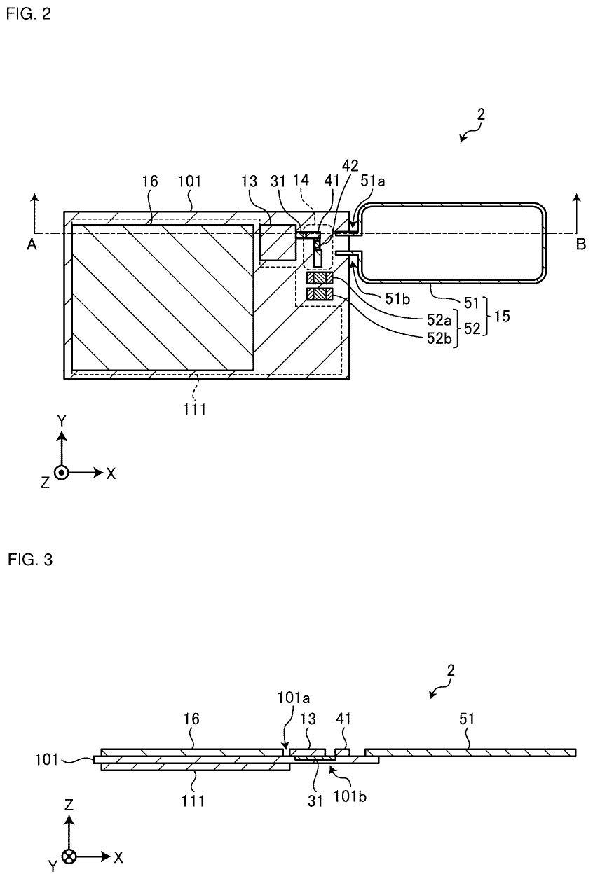

FIGS. 2 and 3 are diagrams illustrating layouts of the wireless power transmission device according to the first embodiment. The wireless power transmission device 2 has a configuration in which components are mounted on a substrate 101. FIG. 2 is a plan view of a principal surface of the substrate 101. FIG. 3 a cross-sectional view along A-B line in FIG. 2.

The substrate 101 corresponds to an example of “circuit board” of the present disclosure.

Plan view refers to viewing the substrate 101 in a direction perpendicular to the principal surface of the substrate 101.

For ease of understanding the layouts of the wireless power transmission device 2, the following description uses X-axis, Y-axis, and Z-axis directions. The X-axis, the Y-axis, and the Z-axis merely represent three axes orthogonal to one another.

The material of the substrate 101 is, for example, glass epoxy. However, the present disclosure is not limited to this. A first principal surface 101a of the substrate 101 (the principal surface on Z-axis distal end side, the principal surface on the viewer proximal side of FIG. 2, the principal surface on the upper side in FIG. 3) and a second principal surface 101b (the principal surface on Z-axis proximal end side, the principal surface on the viewer distal side of FIG. 2, the principal surface on the lower side in FIG. 3) are parallel to the X-Y plane.

The control semiconductor device 16 is mounted on the X-axis proximal end side (on the left side in FIGS. 2 and 3) of the first principal surface 101a of the substrate 101.

The power semiconductor device 13 is mounted on the Y-axis distal end side (the upper side in FIG. 2) of the first principal surface 101a of the substrate 101 and adjacent to the control semiconductor device 16 on the X-axis distal end side (adjacent on the right side in FIGS. 2 and 3).

The drain pattern 31 is formed in a first metal layer in the first principal surface 101a of the substrate 101 (the outermost metal layer on the Z-axis distal end side, the top metal layer on the viewer proximal side of FIG. 2, the uppermost metal layer on the upper side in FIG. 3). A first end of the drain pattern 31 (the end on the X-axis proximal end side, the end on the left side in FIGS. 2 and 3) is positioned under the power semiconductor device 13 (on the Z-axis proximal end side, on the viewer distal side of FIG. 2, on the lower side in FIG. 3), and is electrically connected to the drain of the transistor 22 (see FIG. 1) in the power semiconductor device 13. The drain pattern 31 extends in the X-axis distal direction (in the right direction in FIGS. 2 and 3) from under the power semiconductor device 13.

The low-pass filter 14 is mounted adjacent to the drain pattern 31 on the X-axis distal end side (adjacent on the right side in FIGS. 2 and 3) of the first principal surface 101a of the substrate 101. The first end of the inductor 41 of the low-pass filter 14 is electrically connected to a second end of the drain pattern 31 (the end on the X-axis distal end side, the end on the right side in FIGS. 2 and 3). The second end of the inductor 41 is electrically connected to the first end of the capacitor 42 (the end on the Y-axis distal end side, the end on the upper side in FIG. 2).

The resonant capacitor 52 is mounted adjacent to the low-pass filter 14 on the Y-axis proximal end side (adjacent on the lower side in FIG. 2) of the first principal surface 101a of the substrate 101. In the resonant capacitor 52, a capacitor 52a and a capacitor 52b are connected in parallel to each other.

A first end 51a and a second end 51b of the power transmission coil 51 are mounted adjacent to the low-pass filter 14 on the X-axis distal end side (adjacent on the right side in FIG. 2) of the first principal surface 101a of the substrate 101. The power transmission coil 51 extends in parallel to the X-Y plane and clockwise from the first end 51a to the second end 51b. In the embodiment, an arc-shaped portion of the power transmission coil 51 does not overlap the substrate 101 in plan view. However, the present disclosure is not limited to this.

A heat spreader 111 is mounted on the second principal surface 101b of the substrate 101. The heat spreader 111 is, for example, metal (for example, copper (Cu)). The metal may be alloy.

The heat spreader 111 dissipates heat transferred from the substrate 101.

The heat spreader 111 overlaps the entire control semiconductor device 16 in plan view. As a result, the heat spreader 111 forms a first stray capacitance with the control semiconductor device 16.

Therefore, the heat spreader 111 causes the ground potential of the control semiconductor device 16 to be stabilized through the first stray capacitance, and causes radiation of electromagnetic noise to be suppressed.

In plan view, the heat spreader 111 does not overlap any of the power semiconductor device 13, the low-pass filter 14, and the power-transmission resonant circuit 15 (the resonant capacitor 52 and the power transmission coil 51). As a result, the heat spreader 111 does not form a stray capacitance with any of the power semiconductor device 13, the low-pass filter 14, and the power-transmission resonant circuit 15.

Therefore, in the wireless power transmission device 2, radiation of switching noise from the power semiconductor device 13, the low-pass filter 14, and the power-transmission resonant circuit 15 is suppressed.

The area of the heat spreader 111 in plan view is preferably greater than the area of the power semiconductor device 13 in plan view.

As a result, in the wireless power transmission device 2, heat generated from the power semiconductor device 13 may be diffused to the heat spreader 111 having a wide area, and the temperature of the power semiconductor device 13 may be reduced.

The thermal resistance between the heat spreader 111 and the substrate 101 is preferably less than that between the drain pattern 31 and the substrate 101.

As a result, heat generated from the power semiconductor device 13 is more readily transferred to the heat spreader 111 than to the drain pattern 31. Therefore, the temperature of the power semiconductor device 13 may be reduced in the wireless power transmission device 2.

Heat generated from the power semiconductor device 13 is more readily transferred to the heat spreader 111 than to the drain pattern 31. As a result, the size of the drain pattern 31 may be reduced in the wireless power transmission device 2. Therefore, noise radiated from the drain pattern 31 may be reduced in the wireless power transmission device 2.

The thermal conductivity of glass epoxy which is the material of the substrate 101 is, for example, 0.62 W/m·K. The thermal conductivity of the material of the heat spreader 111 is preferably greater than that of the material of the substrate 101. For example, the thermal conductivity of the heat spreader 111 is preferably greater than or equal to 2.0 W/m·K.

As a result, heat generated from the power semiconductor device 13 does not remain in the substrate 101, and is transferred to the heat spreader 111. Therefore, the temperature of the power semiconductor device 13 may be reduced in the wireless power transmission device 2.

### Effects

[1] In plan view, the heat spreader 111 overlaps the entire control semiconductor device 16. As a result, the heat spreader 111 forms the first stray capacitance with the control semiconductor device 16. Therefore, the heat spreader 111 causes the ground potential of the control semiconductor device 16 to be stabilized through the first stray capacitance, and causes radiation of electromagnetic noise to be suppressed.

As a result, in the wireless power transmission device 2, a local temperature rise in the substrate 101 may be suppressed while a temperature rise in the power semiconductor device 13 may be suppressed. In addition, operation of the control semiconductor device 16 may be stabilized while radiated noise may be suppressed.
[2] In plan view, the heat spreader 111 does not overlap the power-transmission resonant circuit 15. As a result, the heat spreader 111 does not form a stray capacitance with the power-transmission resonant circuit 15.

Therefore, switching noise radiated from the power-transmission resonant circuit 15 may be suppressed in the wireless power transmission device 2.
[3] The area of the heat spreader 111 in plan view is preferably greater than that of the power semiconductor device 13 in plan view.

As a result, in the wireless power transmission device 2, heat generated from the power semiconductor device 13 may be diffused to the heat spreader 111 having a wide area, and the temperature of the power semiconductor device 13 may be reduced.
[4] The thermal resistance between the heat spreader 111 and the substrate 101 is preferably less than that between the drain pattern 31 and the substrate 101.

As a result, heat generated from the power semiconductor device 13 is more readily transferred to the heat spreader 111 than to the drain pattern 31. Therefore, the temperature of the power semiconductor device 13 may be reduced in the wireless power transmission device 2.

Heat generated from the power semiconductor device 13 is more readily transferred to the heat spreader 111 than to the drain pattern 31. Thus, the size of the drain pattern 31 may be reduced in the wireless power transmission device 2. Therefore, noise radiated from the drain pattern 31 may be reduced in the wireless power transmission device 2.
[5] The thermal conductivity of the material of the heat spreader 111 is preferably greater than that of the material of the substrate 101. For example, the thermal conductivity of the material of the heat spreader 111 is preferably greater than or equal to 2.0 W/m·K.

As a result, heat generated from the power semiconductor device 13 does not remain in the substrate 101, and is transferred to the heat spreader 111. Therefore, the temperature of the power semiconductor device 13 may be reduced in the wireless power transmission device 2.

### SECOND EMBODIMENT

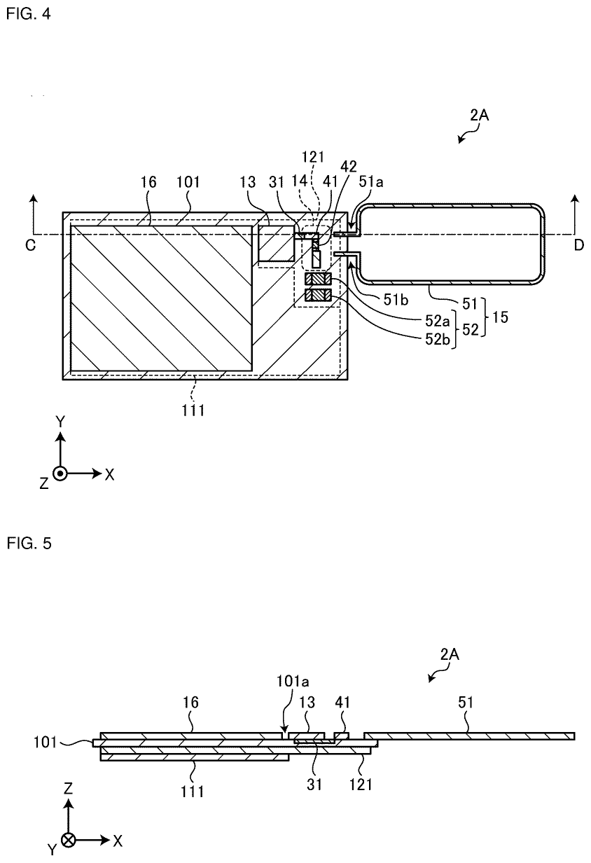

FIGS. 4 and 5 illustrate layouts of a wireless power transmission device according to the second embodiment. FIG. 4 is a plan view of a principal surface of the substrate 101. FIG. 5 is a cross-sectional view along C-D line in FIG. 4.

Compared with the wireless power transmission device 2 (see FIGS. 2 and 3), a wireless power transmission device 2A further includes a TIM (Thermal Interface Material) member 121.

The TIM member 121 is, for example, a member in which boron nitride (BN), aluminum nitride (AlN), alumina (Al₂O₃), or the like is applied to resin. However, the present disclosure is not limited to this.

The TIM member 121 is mounted over substantially the entire surface of the second principal surface 101b of the substrate 101. The heat spreader 111 is mounted on the TIM member 121 on the Z-axis proximal end side (on the viewer distal side of FIG. 4, on the lower side in FIG. 5). That is, the TIM member 121 is mounted between the substrate 101 and the heat spreader 111.

### Effects

The TIM member 121 between the substrate 101 and the heat spreader 111 facilitates transferring heat in the substrate 101 to the heat spreader 111.

As a result, the temperature of the power semiconductor device 13 may be further reduced in the wireless power transmission device 2A.

### THIRD EMBODIMENT

### Circuit Configuration of Wireless Power Transceiver Device

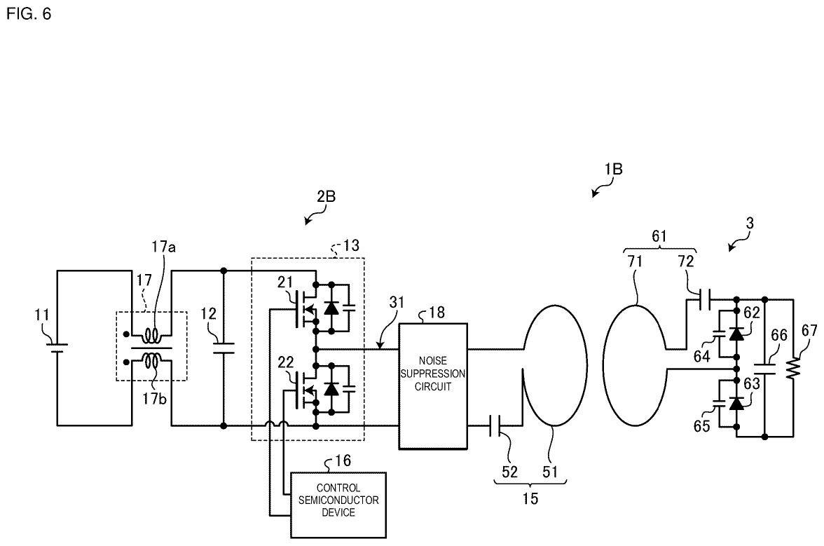

FIG. 6 is a diagram illustrating the circuit configuration of a wireless power transceiver device including a wireless power transmission device according to a third embodiment. A wireless power transceiver device 1B includes a wireless power transmission device 2B and the wireless power reception device 3.

Compared with the wireless power transmission device 2 (see FIG. 1), the wireless power transmission device 2B further includes a common-mode choke coil 17. Compared with the wireless power transmission device 2, the wireless power transmission device 2B includes a noise suppression circuit 18 instead of the low-pass filter 14.

The common-mode choke coil 17 suppresses common-mode noise of a power supply line. The noise suppression circuit 18 suppresses noise of the rectangular-wave voltage applied to the power-transmission resonant circuit 15.

A first winding 17a of the common-mode choke coil 17 is electrically connected, at its first end, to the high-potential-side terminal of the direct-current power supply 11. The first winding 17a of the common-mode choke coil 17 is electrically connected, at its second end, to the first end of the smoothing capacitor 12.

A second winding 17b of the common-mode choke coil 17 is electrically connected, at its first end, to the low-potential-side terminal of the direct-current power supply 11. The second winding 17b of the common-mode choke coil 17 is electrically connected, at its second end, to the second end of the smoothing capacitor 12.

The noise suppression circuit 18 is, for example, a filter or a choke coil.

### Layout of Wireless Power Transmission Device

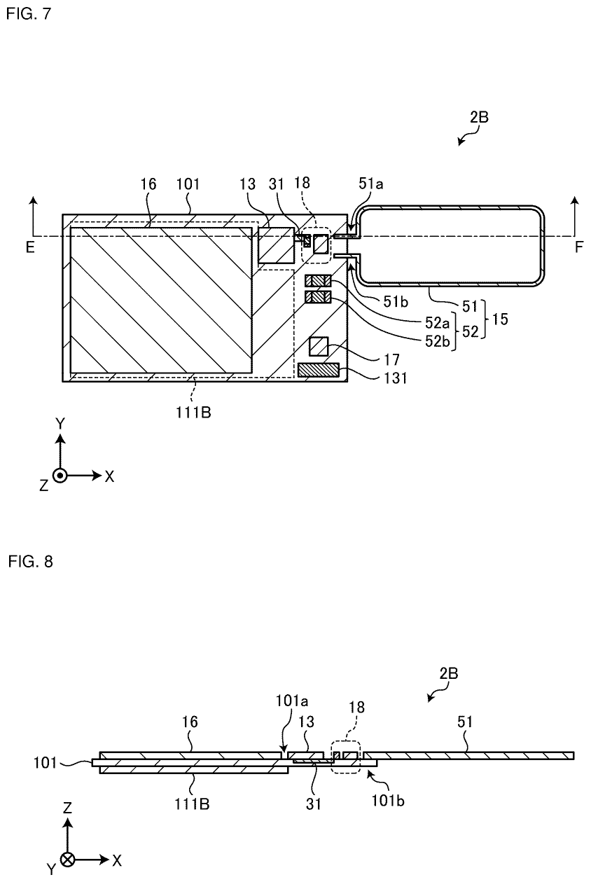

FIGS. 7 and 8 are diagrams illustrating layouts of the wireless power transmission device according to the third embodiment. FIG. 7 is a plan view of a principal surface of the substrate 101. FIG. 8 is a cross-sectional view along E-F line in FIG. 7.

The noise suppression circuit 18 is mounted adjacent to the drain pattern 31 on the X-axis distal end side (adjacent on the right side in FIGS. 7 and 8) of the first principal surface 101a of the substrate 101.

The resonant capacitor 52 is mounted adjacent to the noise suppression circuit 18 on the Y-axis proximal end side (adjacent on the lower side in FIG. 7) of the first principal surface 101a of the substrate 101.

The common-mode choke coil 17 is mounted adjacent to the resonant capacitor 52 on the Y-axis proximal end side (adjacent on the lower side in FIG. 7) of the first principal surface 101a of the substrate 101.

A power supply input section 131 (power supply input electrode) is formed adjacent to the common-mode choke coil 17 on the Y-axis proximal end side (adjacent on the lower side in FIG. 7) of the first principal surface 101a of the substrate 101.

A heat spreader 111B is mounted on the second principal surface 101b of the substrate 101.

In plan view, the heat spreader 111B overlaps the entire control semiconductor device 16. As a result, the heat spreader 111B forms the first stray capacitance with the control semiconductor device 16. Therefore, the heat spreader 111B causes the ground potential of the control semiconductor device 16 to be stabilized through the first stray capacitance, and causes radiation of electromagnetic noise to be suppressed.

In plan view, the heat spreader 111B does not overlap any of the power semiconductor device 13, the noise suppression circuit 18, the power-transmission resonant circuit 15 (the resonant capacitor 52 and the power transmission coil 51), the common-mode choke coil 17, and the power supply input section 131. As a result, the heat spreader 111B does not form a stray capacitance with any of the power semiconductor device 13, the noise suppression circuit 18, the power-transmission resonant circuit 15, the common-mode choke coil 17, and the power supply input section 131.

Therefore, radiation of switching noise from the power semiconductor device 13, the noise suppression circuit 18, the power-transmission resonant circuit 15, the common-mode choke coil 17, and the power supply input section 131 may be suppressed in the wireless power transmission device 2B.

The area of the heat spreader 111B in plan view is preferably greater than that of the power semiconductor device 13 in plan view.

As a result, in the wireless power transmission device 2B, heat generated from the power semiconductor device 13 may be diffused to the heat spreader 111B having a wide area, and the temperature of the power semiconductor device 13 may be reduced.

The thermal resistance between the heat spreader 111B and the substrate 101 is preferably less than that between the drain pattern 31 and the substrate 101.

As a result, heat generated from the power semiconductor device 13 is more readily transferred to the heat spreader 111B than to the drain pattern 31. Therefore, the temperature of the power semiconductor device 13 may be reduced in the wireless power transmission device 2B.

Heat generated from the power semiconductor device 13 is more readily transferred to the heat spreader 111B than to the drain pattern 31. As a result, the size of the drain pattern 31 may be reduced in the wireless power transmission device 2B. Therefore, noise radiated from the drain pattern 31 may be reduced in the wireless power transmission device 2B.

The thermal conductivity of the material of the heat spreader 111B is preferably greater than that of the material of the substrate 101. For example, the thermal conductivity of the material of the heat spreader 111B is preferably greater than or equal to 2.0 W/m·K.

As a result, heat generated from the power semiconductor device 13 does not remain in the substrate 101, and is transferred to the heat spreader 111B. Therefore, the temperature of the power semiconductor device 13 may be reduced in the wireless power transmission device 2B.

### Effects

[1] In plan view, the heat spreader 111B overlaps the entire control semiconductor device 16. As a result, the heat spreader 111B forms the first stray capacitance with the control semiconductor device 16. Therefore, the heat spreader 111B causes the ground potential of the control semiconductor device 16 to be stabilized through the first stray capacitance, and causes radiation of electromagnetic noise to be suppressed.

As a result, in the wireless power transmission device 2B, a local temperature rise in the substrate 101 may be suppressed while a temperature rise in the power semiconductor device 13 may be suppressed. In addition, operation of the control semiconductor device 16 may be stabilized while radiated noise may be suppressed.
[2] In plan view, the heat spreader 111B does not overlap the power-transmission resonant circuit 15. As a result, the heat spreader 111B does not form a stray capacitance with the power-transmission resonant circuit 15.

Therefore, switching noise radiated from the power-transmission resonant circuit 15 may be suppressed in the wireless power transmission device 2B.
[3] The area of the heat spreader 111B in plan view is preferably greater than that of the power semiconductor device 13 in plan view.

As a result, in the wireless power transmission device 2B, heat generated from the power semiconductor device 13 may be diffused to the heat spreader 111B having a wide area, and the temperature of the power semiconductor device 13 may be reduced.
[4] The thermal resistance between the heat spreader 111B and the substrate 101 is preferably less than that between the drain pattern 31 and the substrate 101.

As a result, heat generated from the power semiconductor device 13 is more readily transferred to the heat spreader 111B than to the drain pattern 31. Therefore, the temperature of the power semiconductor device 13 may be reduced in the wireless power transmission device 2B.

Heat generated from the power semiconductor device 13 is more readily transferred to the heat spreader 111B than to the drain pattern 31. Thus, the size of the drain pattern 31 may be reduced in the wireless power transmission device 2B. Therefore, noise radiated from the drain pattern 31 may be reduced in the wireless power transmission device 2B.
[5] The thermal conductivity of the material of the heat spreader 111B is preferably greater than that of the material of the substrate 101. For example, the thermal conductivity of the material of the heat spreader 111B is preferably greater than or equal to 2.0 W/m·K.

As a result, heat generated from the power semiconductor device 13 does not remain in the substrate 101, and is transferred to the heat spreader 111B. Therefore, the temperature of the power semiconductor device 13 may be reduced in the wireless power transmission device 2B.

### FOURTH EMBODIMENT

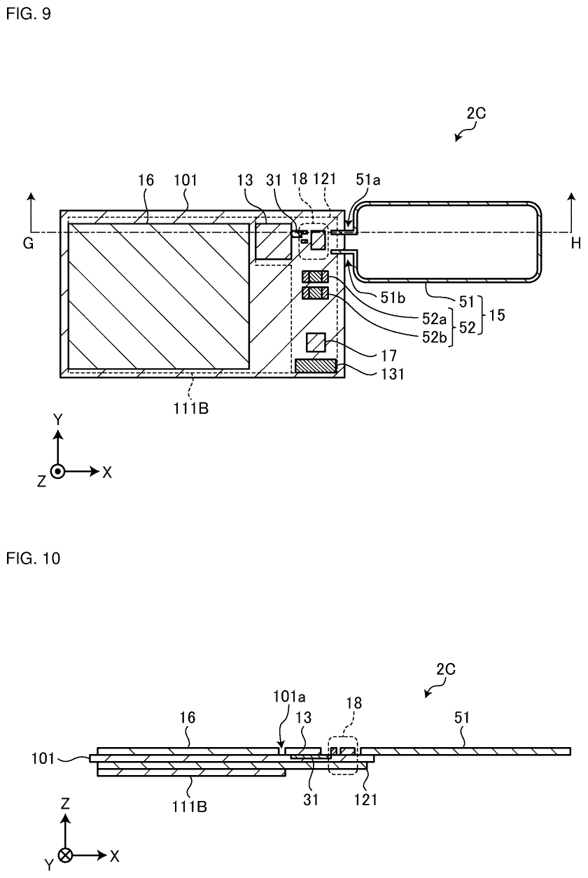

FIGS. 9 and 10 are diagrams illustrating layouts of a wireless power transmission device according to a fourth embodiment. FIG. 9 is a plan view of a principal surface of the substrate 101. FIG. 10 is a cross-sectional view along G-H line in FIG. 9.

Compared with the wireless power transmission device 2B (see FIGS. 7 and 8), a wireless power transmission device 2C further includes the TIM member 121.

The TIM member 121 is mounted over substantially the entire surface of the second principal surface 101b of the substrate 101. The heat spreader 111B is mounted on the Z-axis proximal end side of the TIM member 121 (on the viewer distal side of FIG. 9, on the lower side in FIG. 10). That is, the TIM member 121 is mounted between the substrate 101 and the heat spreader 111B.

### Effects

The TIM member 121 between the substrate 101 and the heat spreader 111B facilitates transferring heat in the substrate 101 readily to the heat spreader 111B.

As a result, the temperature of the power semiconductor device 13 may be further reduced in the wireless power transmission device 2C.

### CONFIGURATION EXAMPLE OF PRESENT DISCLOSURE

The present disclosure may employ the following configurations.
(1) A wireless power transmission device comprising a circuit board; a power-transmission resonant circuit mounted on a first principal surface of the circuit board; a noise suppression circuit that is mounted on the first principal surface of the circuit board and that is electrically connected to the power-transmission resonant circuit; a power semiconductor element that is mounted on the first principal surface of the circuit board and that includes a switching element which applies a periodically-changing voltage to the power-transmission resonant circuit; a control circuit that is mounted on the first principal surface of the circuit board and that controls the switching element; and a heat spreader that is thermally in contact with a second principal surface of the circuit board. An electrical pattern which electrically connects a switching node of the power semiconductor element to the noise suppression circuit is formed in the circuit board, The heat spreader dissipates heat which is generated by the power semiconductor element and which is transferred through the electrical pattern and the circuit board; overlaps the entire control circuit when viewed in a direction perpendicular to the first principal surface, forms a first stray capacitance with the control circuit, and causes ground potential of the control circuit to be stabilized through the first stray capacitance and causes radiation of electromagnetic noise to be suppressed; and does not overlap any of the power semiconductor element and the noise suppression circuit when viewed in the direction perpendicular to the first principal surface, and does not form a structural stray capacitance with any of the power semiconductor element and the noise suppression circuit.
(2) The wireless power transmission device according to (1), wherein the heat spreader does not overlap the power-transmission resonant circuit when viewed in the direction perpendicular to the first principal surface, and does not form a stray capacitance with the power-transmission resonant circuit.
(3) The wireless power transmission device according to (1) or (2), wherein the area of the heat spreader is greater than the area of the power semiconductor element.
(4) The wireless power transmission device according to any one of (1) to (3), wherein a thermal resistance between the heat spreader and the circuit board is less than a thermal resistance between the electrical pattern and the circuit board.
(5) The wireless power transmission device according to any one of (1) to (4), wherein a thermal conductivity of material of the heat spreader is greater than a thermal conductivity of material of the circuit board.
(6) The wireless power transmission device according to (5), wherein the thermal conductivity of material of the heat spreader is greater than or equal to 2.0 W/m·K.
(7) The wireless power transmission device according to any one of (1) to (6), further including a TIM (Thermal Interface Material) member disposed between the second principal surface of the circuit board and the heat spreader.

The embodiments described above are provided to facilitate understanding of the present disclosure, not to interpret the present disclosure limitedly. The present disclosure may be changed/improved without departing from the gist thereof. In addition, the present disclosure encompasses its equivalents.

What is claimed is:

1. A wireless power transmission device comprising:
a circuit board;
a power-transmission resonant circuit mounted on a first principal surface of the circuit board;
a noise suppression circuit that is mounted on the first principal surface of the circuit board and that is electrically connected to the power-transmission resonant circuit;
a power semiconductor element that is mounted on the first principal surface of the circuit board and that includes a switching element which is configured to apply a periodically-changing voltage to the power-transmission resonant circuit;
a control circuit that is mounted on the first principal surface of the circuit board and that is configured to control the switching element; and
a heat spreader that is thermally in contact with a second principal surface of the circuit board,
wherein
an electrical pattern which electrically connects a switching node of the power semiconductor element to the noise suppression circuit is in the circuit board,
the heat spreader is configured to dissipate heat which is generated by the power semiconductor element and which is transferred through the electrical pattern and the circuit board;
the heat spreader overlaps the entire control circuit when viewed in a direction perpendicular to the first principal surface, is configured to create a first stray capacitance with the control circuit, and is configured to cause ground potential of the control circuit to be stabilized through the first stray capacitance and cause radiation of electromagnetic noise to be suppressed; and
the heat spreader does not overlap any of the power semiconductor element and the noise suppression circuit when viewed in the direction perpendicular to the first principal surface, and does not create a structural stray capacitance with any of the power semiconductor element and the noise suppression circuit.

2. The wireless power transmission device according to claim 1, wherein
the heat spreader does not overlap the power-transmission resonant circuit when viewed in the direction perpendicular to the first principal surface, and does not create a stray capacitance with the power-transmission resonant circuit.

3. The wireless power transmission device according to claim 1, wherein
an area of the heat spreader is greater than an area of the power semiconductor element.

4. The wireless power transmission device according to claim 1, wherein
a thermal resistance between the heat spreader and the circuit board is less than a thermal resistance between the electrical pattern and the circuit board.

5. The wireless power transmission device according to claim 1, wherein
a thermal conductivity of material of the heat spreader is greater than a thermal conductivity of material of the circuit board.

6. The wireless power transmission device according to claim 5, wherein
the thermal conductivity of material of the heat spreader is greater than or equal to 2.0 W/m·K.

7. The wireless power transmission device according to claim 1, further comprising:
a TIM (Thermal Interface Material) member between the second principal surface of the circuit board and the heat spreader.

8. The wireless power transmission device according to claim 2, wherein
an area of the heat spreader is greater than an area of the power semiconductor element.

9. The wireless power transmission device according to claim 2, wherein
a thermal resistance between the heat spreader and the circuit board is less than a thermal resistance between the electrical pattern and the circuit board.

10. The wireless power transmission device according to claim 3, wherein
a thermal resistance between the heat spreader and the circuit board is less than a thermal resistance between the electrical pattern and the circuit board.

11. The wireless power transmission device according to claim 2, wherein
a thermal conductivity of material of the heat spreader is greater than a thermal conductivity of material of the circuit board.

12. The wireless power transmission device according to claim 3, wherein
a thermal conductivity of material of the heat spreader is greater than a thermal conductivity of material of the circuit board.

13. The wireless power transmission device according to claim 4, wherein
a thermal conductivity of material of the heat spreader is greater than a thermal conductivity of material of the circuit board.

14. The wireless power transmission device according to claim 11, wherein
the thermal conductivity of material of the heat spreader is greater than or equal to 2.0 W/m·K.

15. The wireless power transmission device according to claim 12, wherein
the thermal conductivity of material of the heat spreader is greater than or equal to 2.0 W/m·K.

16. The wireless power transmission device according to claim 2, further comprising:
a TIM (Thermal Interface Material) member between the second principal surface of the circuit board and the heat spreader.

17. The wireless power transmission device according to claim 3, further comprising:
a TIM (Thermal Interface Material) member between the second principal surface of the circuit board and the heat spreader.

18. The wireless power transmission device according to claim 4, further comprising:
a TIM (Thermal Interface Material) member between the second principal surface of the circuit board and the heat spreader.

19. The wireless power transmission device according to claim 5, further comprising:
a TIM (Thermal Interface Material) member between the second principal surface of the circuit board and the heat spreader.

20. The wireless power transmission device according to claim 6, further comprising:
a TIM (Thermal Interface Material) member between the second principal surface of the circuit board and the heat spreader.
